(19) United States
(12) Patent Application Publication
(10) Pub. No.: US 2021/0086654 A1
(43) Pub. Date: Mar. 25, 2021

(54) DISCARDED VEHICLE MANAGEMENT APPARATUS

(71) Applicant: Honda Motor Co., Ltd., Tokyo (JP)

(72) Inventors: Yu Murai, Wako-shi (JP); Tsubasa Uchida, Wako-Shi (JP); Yuki Morita, Tokyo (JP)

(21) Appl. No.: 17/028,983

(22) Filed: Sep. 22, 2020

(30) Foreign Application Priority Data
Sep. 24, 2019 (JP) 2019-172493

(51) Int. Cl. B60L 53/80

(52) U.S. Cl. CPC B60L 53/80

(57) ABSTRACT

A discarded vehicle management apparatus including a communication unit configured to communicate with a vehicle on which a battery is mounted, and an electronic control unit including a microprocessor and a memory connected to the microprocessor. The microprocessor is configured to perform: acquiring a vehicle information including a battery removal information indicating a removal of the battery from the vehicle; and determining whether the vehicle has been discarded based on the vehicle information.

### CROSS-REFERENCE TO RELATED APPLICATION

This application is based upon and claims the benefit of priority from Japanese Patent Application No. 2019-172493 filed on Sep. 24, 2019, the content of which is incorporated herein by reference.

### BACKGROUND OF THE INVENTION

### Field of the Invention

This invention relates to a discarded vehicle management apparatus configured to manage an information on a discarded vehicle.

### Description of the Related Art

Conventionally, as a device of this type, there has been known an apparatus that stores discarded vehicle information transmitted from a terminal of a vendor such as the dealer of vehicle sales or the like after a procedure of discarded vehicle is performed by the vehicle, and further transmits the discarded vehicle information to a terminal of a dismantler performing a dismantling operation of the vehicle. Such an apparatus is described, for example, in Japanese Unexamined Patent Publication No. 2009-157433 (JP2009-157433A). In the apparatus described in JP2009-157433A, when the procedure of the discarded vehicle is performed by the vehicle sales dealer, the discarded vehicle information is inputted through a manipulation of an operator of the vehicle sales dealer.

However, the procedure of the discarded vehicle is not always carried out by a vendor such as a vehicle sales dealer.

Therefore, it is difficult to grasp accurately the state of discarded vehicles of various vehicles only by the discarded vehicle information inputted through the manipulation of the operator of the vehicle sales dealer.

### SUMMARY OF THE INVENTION

An aspect of the present invention is a discarded vehicle management apparatus including: a communication unit configured to communicate with a vehicle on which a battery is mounted; and an electronic control unit including a microprocessor and a memory connected to the microprocessor. The microprocessor is configured to perform: acquiring a vehicle information including a battery removal information indicating a removal of the battery from the vehicle; and determining whether the vehicle has been discarded based on the vehicle information.

### BRIEF DESCRIPTION OF THE DRAWINGS

The objects, features, and advantages of the present invention will become clearer from the following description of embodiments in relation to the attached drawings, in which:

FIG. 1 is a diagram schematically showing a configuration of main components of a travel drive system of a motor-driven vehicle to which a discarded vehicle management apparatus according to an embodiment of the invention is applied;

FIG. 2 is a block diagram schematically showing an overall configuration of a discarded vehicle management system including the discarded vehicle management apparatus according to the embodiment of the present invention;

FIG. 3 is a flowchart showing an example of a processing performed by a CPU of a server device of FIG. 2; and

FIG. 4 is a block diagram showing a modification of FIG. 2.

### DETAILED DESCRIPTION OF THE INVENTION

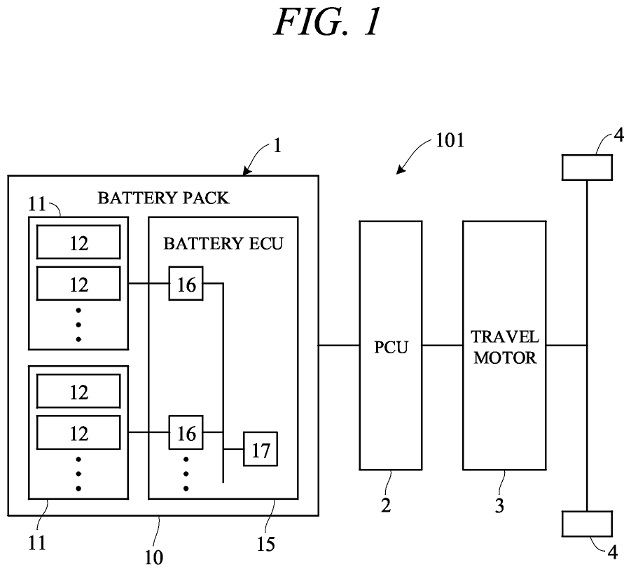

Hereinafter, an embodiment of the present invention is explained with reference to FIGS. 1 to 4. A discarded vehicle management apparatus according to the embodiment of the present invention is configured to determine whether a vehicle has been discarded, based on whether a battery mounted on the vehicle is removed or not removed. The vehicle in the discarded vehicle state is a vehicle in a state in which the registration of the vehicle is deleted and the vehicle license plate is removed. The vehicles in the discarded vehicle state are dismantled by dismantlers, and some or all of the parts are reused or recycled. Alternatively, it is re-registered without being disassembled.

FIG. 1 is a diagram schematically showing the configuration of main components of the travel drive system of a motor-driven vehicle 101 (may be simply referred to as the vehicle) to which the discarded vehicle management apparatus according to the present embodiment is applied. As shown in FIG. 1, the vehicle 101 includes a battery 1, a power control unit (PCU) 2, and a travel motor 3.

The battery 1 is configured as a unit by a single battery pack 10. The battery 1 may be configured by multiple battery packs 10. If the battery 1 is configured by the single battery pack 10 as seen in the present embodiment, the battery 1 and battery pack 10 are the same. For this reason, hereafter, the battery pack 10 may be referred to as the battery 1, or the battery 1 may be referred to as the battery pack 10.

The battery pack 10 includes multiple battery modules 11 and a battery ECU (Electronic Control Unit) 15. The battery modules 11 are connected with each other in series or in parallel through a bus bar or the like. These battery modules 11 each include multiple cells 12. The cell 12 is, for example, a flat lithium-ion cell sealed by a laminate film and includes electrode plates. The cells 12 are housed in the sealed housing of the battery module 11 so as to connect the electrode plates in series or in parallel, forming a lithium-ion battery.

The battery ECU 15 includes multiple detection circuits 16 that detect respective states of the battery modules 11 and a detection circuit 17 that detects a state of the battery pack 10. For example, the detection circuits 16 each include sensors that detect the physical quantities, such as the current, voltage, and temperature, of the corresponding battery module 11. The detection circuits 16 calculate a state of charge SOC and a state of health SOH of the respective battery modules 11 on the basis of the detected physical quantities. The detection circuit 17 calculates the SOC and SOH of the entire battery on the basis of signals from the detection circuits 16.

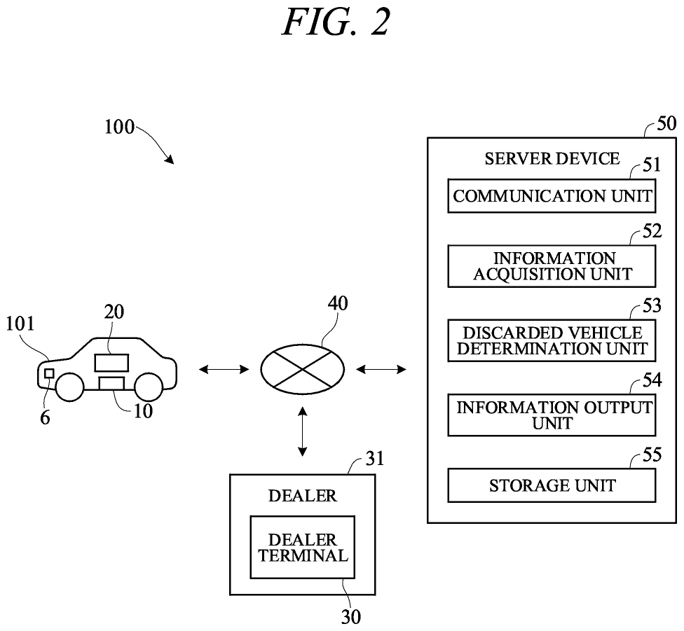

When the battery pack 10 is removed from the vehicle 101, the detection circuits 16 and 17 output, for example, an error signal. With or without outputting this error signal, the vehicle terminal 20 (FIG. 2) communicating with the battery ECU 15 or the battery ECU 15 can detect a detachment of the battery pack 10 from the vehicle 101. Further, by the presence or absence of a change from the error signal to the normal signal, it is possible to detect an attachment of the battery pack 10 to the vehicle 101. That is, it is possible to detect the attachment and detachment (mounting and removal) of the battery pack 10. A detector such as a sensor or a switch for detecting the attachment and detachment of the battery pack 10 is provided, and it is also possible to detect the attachment and detachment of the battery pack 10 by a signal from the detector.

The battery 1 supplies power to the power control unit 2 through a junction box (not shown). The power control unit 2 includes an inverter circuit. The power control unit 2 converts the direct current from the battery 1 into alternating current using the inverter circuit and supplies the drive power to the travel motor 3. Thus, the travel motor 3 is driven, drive wheels 4 are rotationally driven, and the vehicle 101 travels. The battery 1 is a large capacity battery for driving the traveling motor, and as shown in FIG. 2, a small capacity auxiliary battery 6 (e.g., a lead-acid battery) is also mounted on the vehicle 101. Therefore, even when the battery pack 10 is removed, power can be supplied to the vehicle terminal 20 (FIG. 20) or the like.

FIG. 2 is a block diagram schematically showing the overall configuration of a discarded vehicle management system 100 including the discarded vehicle management apparatus according to the present embodiment. As shown in FIG. 2, the discarded vehicle management system 100 includes a vehicle terminal 20 mounted on the vehicle 101, a terminal (dealer terminal 30) provided at a dealer 31 at which a business such as vehicle sales and a procedure of discarded vehicle is performed, and a server device 50. The server device 50 mainly constitutes the discarded vehicle management apparatus according to the present embodiment, and is provided at a business office at which a business of the dealer 31 is managed.

The vehicle terminal 20, dealer terminal 30, and server device 50 are connected to a network 40, such as a public wireless communication network typified by the Internet network or mobile telephone network, and are able to communicate with each other through the network 40. Examples of the network 40 also include closed communication networks provided for predetermined control areas, for example, wireless LANs, Wi-Fi (registered trademark), and the like.

The vehicle terminal 20 includes an arithmetic processing unit including a CPU (microprocessor), memory such as ROM or RAM, and other peripheral circuits. The vehicle terminal 20 includes, as functional configurations, a communication unit that makes communications through the network 40. The vehicle terminal 20 is connected to the battery ECU 15 (FIG. 1), and transmits a vehicle information including an information transmitted from the battery ECU 15 to the server device 50 through the communication unit along with a vehicle ID for identifying the vehicle 101 at a predetermined timing. On the vehicle 101, a small capacity auxiliary battery 6 is mounted in addition to a large capacity travel battery 1 (battery pack 10).

The vehicle information transmitted from the battery ECU 15 includes information indicating an attachment and detachment of the battery pack 10 detected in the battery ECU 15, i.e., a battery removal information indicating a removal of the battery pack 10 from the vehicle 101 and a battery mounting information indicating a mounting of the battery pack 10 to the vehicle 101. When the battery pack 10 is mounted on the vehicle 101, a power supply circuit is formed in the vehicle 101. On the other hand, when the battery pack 10 is removed from the vehicle 101, the power supply circuit is cut-off. Whenever the attachment and detachment of the battery pack 10 is detected by the battery ECU 15, the vehicle terminal 20 transmits signal indicating the detected result to the server device 50 through the communication unit.

The dealer terminal 30 includes an arithmetic processing unit including a CPU (microprocessor), memory such as ROM or RAM, and other peripheral circuits. The dealer terminal 30 includes, as functional configurations, a communication unit that makes communications through the network 40. The dealer terminal 30 can also transmit to the server device 50 together with the vehicle ID, various information of the vehicle 101 inputted by the operator, for example, whether the vehicle 101 is scheduled for being discarded, scheduled date of being discarded, and presence or absence of dismantling after being discarded, i.e., information on scrapping of the vehicle 101 (a discarded vehicle information). Even if the discarded vehicle information is not transmitted from the dealer terminal 30, the server device 50 can determine whether or not the vehicle 101 is in the discarded vehicle state, i.e., whether or not the vehicle 101 has been discarded, as described later, based on the information transmitted from the vehicle terminal 20.

The server device 50 is formed, for example, as a single server or as distributed servers consisting of servers having different functions. The server device 50 may be formed as distributed virtual servers created in the cloud environment, which are called cloud servers. The server device 50 includes an arithmetic processing unit including a CPU (microprocessor), memory such as ROM or RAM, and other peripheral circuits.

The server device 50 includes, as functional configurations, a communication unit 51, an information acquisition unit 52, a discarded vehicle determination unit 53, an information output unit 54, and a storage unit 55. In the storage unit 55, a correspondence relationship between the vehicle 101 and the dealer 31 that performs a maintenance or the like of the vehicle 101, that is, a dealer ID for identifying the dealer 31 corresponding to the vehicle ID is stored in advance.

The communication unit 51 is configured to be able to wirelessly communicate with the vehicle terminal 20 and dealer terminal 30 through the network 40. The communication unit 51 communicates with the vehicle terminal 20 and dealer terminal 30 in a predetermined cycle or at a predetermined timing, and receives and transmits various types of information therefrom and thereto.

The information acquisition unit 52 acquires a vehicle information transmitted from the vehicle terminal 20 and a discarded vehicle information transmitted from the dealer terminal 30 along with the vehicle ID. In the vehicle information acquired by the information acquisition unit 52, a battery removal information and battery mounting information transmitted whenever the battery pack 10 is removed and mounted are included. The information acquired by the information acquisition unit 52 stored in the storage unit 55.

The discarded vehicle determination unit 53 determines whether or not the vehicle 101 is in the discarded vehicle state based on the vehicle information acquired by the information acquisition unit 52. More specifically, the discarded vehicle determination unit 53 determines that the vehicle 101 is in the discarded vehicle state, when the communication with the vehicle terminal 20 via the communication unit 51 becomes impossible after the battery removal information is acquired by the information acquisition unit 52. This determination means that the vehicle 101 is predicted to be in the discarded vehicle state by acquiring the battery detachment information, and then when it becomes impossible to communicate with the vehicle 101, the vehicle 101 is finalized to be in the discarded vehicle state.

That is, when the battery pack 10 is repaired or replaced, the battery pack 10 is once detached from the vehicle 101 and then reattached. Therefore, it cannot be determined that the vehicle is in the discarded vehicle state only by removing the battery pack 10. On the other hand, when the vehicle 101 is in the discarded vehicle state, the auxiliary battery 6 is removed from the vehicle 101 and power supply of the vehicle 101 is turned off. Therefore, the communication unit of the vehicle 101 (vehicle terminal 20) is disabled communication. In consideration of this point, the discarded vehicle determination unit 53 determines to be the discarded vehicle state on condition that communication with the vehicle 101 becomes impossible.

In addition, the discarded vehicle determination unit 53 determines that the vehicle 101 is in the discarded vehicle state even when the battery mounting information is not acquired within a predetermined time after the battery removal information is acquired by the information acquisition unit 52. That is, if the battery pack 10 is removed from the vehicle 101 for repairing or replacing the battery pack 10, the battery pack 10 should be mounted on the vehicle 101 again within a predetermined time (e.g., one hour). In consideration of this point, the discarded vehicle determination unit 53 determines that the vehicle 101 is in the discarded vehicle state on condition that the battery mounting information is not acquired within the predetermined time.

When it is determined that the vehicle 101 is in the discarded vehicle state by the discarded vehicle determination unit 53, the information output unit 54 transmits the discarded vehicle information including the determination result to the dealer terminal 30 together with the vehicle ID of the corresponding vehicle 101 via the communication unit 51. More specifically, the information output unit 54 identifies the dealer terminal 30 corresponding to the vehicle ID based on the correspondence relationship stored in advance in the storage unit 55, and outputs the discarded vehicle information to the identified dealer terminal 30. As a result, at the dealer 31, the state of the vehicle 101 can be grasped, and it is possible to provide useful services to the user of the vehicle 101 from the dealer 31. That is, for the user who is determined to be in the discarded vehicle state, it is possible to carry out sales activities of vehicle sales and the like. On the other hand, for the user who is not determined to be in the discarded vehicle state, is it possible to notify guidance such as periodic inspection of the vehicle 101.

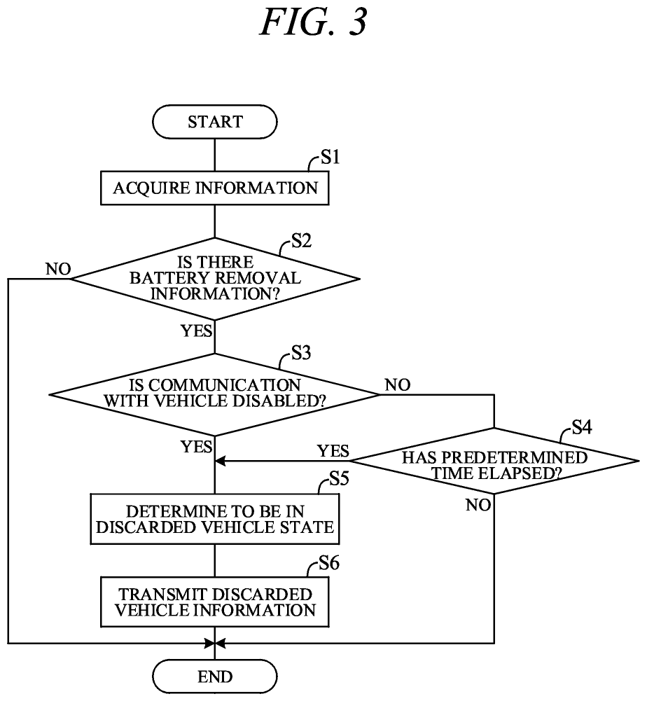

FIG. 3 is a flowchart showing an example of a processing performed by the CPU of the server device 50 in accordance with a predetermined program. The process shown in this flowchart is mainly performed by the information acquisition unit 52, discarded vehicle determination unit 53 and information output unit 54. This process is started, for example, when communication with the vehicle terminal 20 through the communication unit 51 is established, and repeated at a predetermined cycle.

First, in S1 (S: processing step), the server device 50 (CPU) acquires the vehicle information transmitted from the vehicle terminal 20 together with the vehicle ID. Next, in S2, the server device 50 determines whether or not the battery removal information is included in the vehicle information acquired in S1. If the determination in S2 is YES, the server device 50 predicts that the vehicle 101 is in the scrapped vehicle state, and the processing proceeds to S3. On the other hand, if the determination in S2 is NO, the processing ends.

In S3, the server device 50 determines whether or not communication with the vehicle terminal 20 via the communication unit 51 has become impossible. If the determination in S3 is YES, the processing proceeds to S5, and if the determination is NO, the processing proceeds to S4. In S4, the server device 50 determines whether or not a predetermined time has elapsed since it is first determined in S2 that there is battery removal information. That is, when the determination in S2 is initially YES, count of the timer is continued until the determination in S2 is NO, and in S4, it is determined whether or not count value of the timer has reached a predetermined time. If the determination in S4 is YES, the processing proceeds to S5, and if the determination is NO, the processing ends.

In S5, the server device 50 determines that the vehicle 101 is in a discarded vehicle state. That is, the discarded vehicle state of the vehicle 101 is finalized. Next, in S6, the server device 50 identifies the dealer terminal 30 having the dealer ID corresponding to the vehicle ID from the correspondence relationship stored in the storage unit 55, and transmits the discarded vehicle information to the identified dealer terminal 30.

The operation of the discarded vehicle management apparatus according to the present embodiment is summarized as follows. When a procedure for discarding the vehicle 101 is performed, the battery pack 10 is removed from the vehicle 101. Thereafter, when the power source of the communication unit of the vehicle terminal 20 is turned off due to the removal of the auxiliary battery 6 or the like, the communication between the server device 50 and the vehicle terminal 20 becomes impossible, and it is determined that the vehicle 101 is in a discarded vehicle state (S2→S3→S5). Further, even if the power source of the communication unit of the vehicle terminal 20 is not turned off, even when a predetermined time has elapsed since the battery pack 10 is removed, the vehicle 101 is determined to be in the discarded vehicle state (S2→S3→S4→S5).

When it is determined that the vehicle 101 is in the discarded vehicle state, the determination result is transmitted to the terminal 30 of the dealer 31 corresponding to the vehicle 101 (S6). As a result, even when a procedure for discarding the vehicle 101 at a place other than the dealer 31 is performed, the discarded vehicle information of the vehicle 101 can be easily grasped by the dealer 31, and the vehicle information can be appropriately managed. Therefore, it is possible to perform good business activities and the like to the user of the vehicle 101 at an appropriate timing.

The present embodiment can achieve advantages and effects such as the following:

(1) A discarded vehicle management apparatus (server device 50) according to the present embodiment includes: a communication unit 51 communicating with the vehicle terminal 20 of the vehicle 101 on which the battery pack 10 (battery 1) is mounted; an information acquisition unit 52 acquiring a vehicle information including a battery removal information indicating a removal of the battery pack 10 from the vehicle 101; and a discarded vehicle determination unit 53 determining whether the vehicle 101 has been discarded, based on the vehicle information acquired by the information acquisition unit 52 (FIG. 2).

In this manner, in the present embodiment, considering that the battery pack 10 is removed from the vehicle 101 when the vehicle 101 is in the scrapped vehicle state, it is determined whether or not the vehicle is in the discarded vehicle state based on the battery removal information, so that it is possible to accurately grasp the discarded vehicle state of each vehicle 101 on the server device 50 side.

(2) The discarded vehicle determination unit 53 determines that when it is disabled to communicate with the vehicle terminal 20 through the communication unit 51 after the battery removal information is acquired by the information acquisition unit 52, the vehicle 101 has been discarded (FIG. 3). Thus, when the battery pack 10 is temporarily removed from the vehicle 101 by repair or inspection or the like, it can be prevented from mistakenly determining that the vehicle is in the discarded vehicle state, and therefore, it is possible to accurately grasp the vehicle discarded state.

(3) The vehicle information acquired by the information acquisition unit 52 further includes a battery mounting information indicating a remounting of the battery pack 10 to the vehicle 101 from which the battery pack 10 is removed. The discarded vehicle determination unit 53 determines that when the battery mounting information is not acquired within a predetermined time since the battery removal information is acquired by the information acquisition unit 52, the vehicle has been discarded (FIG. 3). Also in this case, when the battery pack 10 is temporarily removed from the vehicle 101 by repair or inspection or the like, it can be prevented from mistakenly determining that the vehicle is in the discarded vehicle state by mistake, and therefore, it is possible to accurately grasp the discarded vehicle state. The battery (battery pack 10) included in the battery mounting information may be the same as or different from the removed battery.

Various modifications of the above embodiment are possible. Some examples are explained in the following. In the above embodiment, the battery 1 as a secondary battery is configured as a lithium ion battery, but the other batteries are similarly removed from the vehicle 101 in the discarded vehicle state. Therefore, the configuration of the battery is not limited to the above configuration. The battery may be composed of a plurality of battery packs.

In the above embodiment, the information acquisition unit 52 acquires the vehicle information including the battery removal information and the battery mounting information, but a vehicle information acquired by a vehicle information acquisition unit is not limited to this. In the above embodiment, the discarded vehicle determination unit 53 determines that after the battery removal information is acquired by the information acquisition unit 52, when communication with the vehicle 101 through the communication unit 51 becomes disabled, or when the battery mounting information is not acquired within a predetermined time since the battery removal information is acquired by the information acquisition unit 52, the vehicle 101 is in the discarded vehicle state. However, as long as it is determined whether or not the vehicle is in the discarded vehicle state based on the vehicle information acquired by a vehicle information acquisition unit, the configuration of a discarded vehicle determination unit may be any configuration.

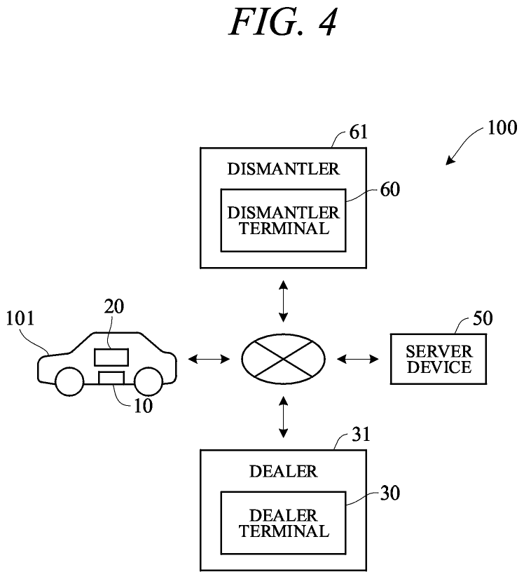

In the above embodiment, the information output unit 54 outputs (transmits) the determination result by the discarded vehicle determination unit 53 to the dealer terminal 30, but the determination result may be transmitted to a terminal of a dismantler or the like. FIG. 4 is a block diagram schematically showing an overall configuration of such a discarded vehicle management system as an example, that is, a block diagram as a modification of FIG. 2. In FIG. 4, in addition to the vehicle terminal 20, the dealer terminal 30 and the server device 50, a terminal (dismantler terminal 60) of a dismantler 61 or the like is communicatively connected via the network 40. Then, when the vehicle 101 is determined to be in a discarded vehicle state by the discarded vehicle determination unit 53, the information output unit 54 transmits the discarded vehicle information to the dismantler terminal 60. As a result, the dismantler 61 can easily and quickly grasp the information on the discarded vehicle, and can smoothly shift the vehicle 101 to the dismantling operation. The information output from the information output unit 54 may be used for grasping the share in the market of the same vehicle type as the vehicle 101.

The present invention can be configured as a discarded vehicle management method, including: acquiring a vehicle information including a battery removal information indicating a removal of a battery 1 mounted on a vehicle 101 from the vehicle 101 through the communication unit 51; and determining whether the vehicle 101 has been discarded based on the acquired vehicle information.

The above embodiment can be combined as desired with one or more of the above modifications. The modifications can also be combined with one another.

According to the present invention, it is possible to accurately grasp discarded vehicle information of various vehicles.

Above, while the present invention has been described with reference to the preferred embodiments thereof, it will be understood, by those skilled in the art, that various changes and modifications may be made thereto without departing from the scope of the appended claims.

What is claimed is:

1. A discarded vehicle management apparatus comprising:
a communication unit configured to communicate with a vehicle on which a battery is mounted; and
an electronic control unit including a microprocessor and a memory connected to the microprocessor, wherein
the microprocessor is configured to perform:
acquiring a vehicle information including a battery removal information indicating a removal of the battery from the vehicle; and
determining whether the vehicle has been discarded based on the vehicle information.

2. The discarded vehicle management apparatus according to claim 1, wherein
the microprocessor is configured to perform
the determining including determining that when it is disabled to communicate with the vehicle through the communication unit after acquiring the battery removal information, the vehicle has been discarded.

3. The discarded vehicle management apparatus according to claim 2, wherein
the vehicle information includes a battery mounting information indicating a remounting of the battery removed from the vehicle or a mounting of another battery to the vehicle, and
the microprocessor is configured to perform
the determining including determining that when the battery mounting information is not acquired within a predetermined time from acquiring the battery removal information, the vehicle has been discarded.

4. A discarded vehicle management system, comprising
the discarded vehicle management apparatus according to claim 1;
a vehicle terminal mounted on the vehicle to communicate with the discarded vehicle management apparatus; and
a dealer terminal provided at a dealer at which the vehicle is sold or managed to communicate with the discarded vehicle management apparatus.

5. The discarded vehicle management system according to claim 4, wherein
the memory included in the discarded vehicle management apparatus is configured to store an information on the dealer corresponding to the vehicle, and
the microprocessor included in the discarded vehicle management apparatus is configured to further perform
identifying the dealer corresponding to the vehicle based on the information stored in the memory when it is determined that the vehicle has been discarded, and transmitting a discarded vehicle information of the vehicle through the communication unit to the dealer terminal of the dealer identified.

6. The discarded vehicle management system according to claim 4, further comprising
a dismantling terminal provided at a dismantler of the vehicle to communicate with the discarded vehicle management apparatus.

7. The discarded vehicle management system according to claim 4, wherein
the battery is a travel battery supplying a power to a travel motor of the vehicle, and
the vehicle includes an auxiliary battery in addition to the travel battery.

8. A discarded vehicle management method comprising:
acquiring a vehicle information including a battery removal information indicating a removal of a battery mounted on a vehicle from the vehicle; and
determining whether the vehicle has been discarded based on the vehicle information.
